(19) United States
(12) Patent Application Publication
(10) Pub. No.: US 2008/0122470 A1
(43) Pub. Date: May 29, 2008

(54) Probe installed to a probe card

(76) Inventor: Wen-Yu Lu, Jiali Township (TW)

Correspondence Address: Wen-Yu Lu, 235 Chung - Ho, Box 8-24, Taipei, omitted

(21) Appl. No.: 11/604,067

(22) Filed: Nov. 27, 2006

(51) Int. Cl. G01R 1/067

(52) U.S. Cl. 324/762

(57) ABSTRACT

A probe installed to a probe card is provided. A tip or a body of the probe are electroplated with a conductive film and the probe card is placed in a vacuum electroplating furnace. Or, the body of the probe is electroplated with an insulating film and the probe card is placed in a vacuum electroplating furnace. Further, a probe with worn conductive film is electroplated again with a conductive film. The conductivity of the probe is increased and the probe is more worn-endurable and friction endurable. The dirt and dregs on the surface of the probe can be reduced. Electromagnetic interference is decreased and the probe can be trimmed easily. The probe is reused again and again and the lifetime of the probe is prolonged. The yield ratio is increased and the cost in testing is reduced.

### FIELD OF THE INVENTION

The present invention relates to a probe installed to a probe card, wherein the conductivity of the probe is increased and the probe is worn-endurable and friction endurable. The dirt and dregs on the surface of the probe is reduced. Electromagnetic interference is decreased and the probe can be trimmed easily. The probe can be reused again and again and the lifetime of the probe is prolonged. The yield ratio is increased and the cost in testing is reduced.

### BACKGROUND OF THE INVENTION

Generally, the object to be tested (such as wafers, ICs, DRAMs, etc.) must be tested in a test machine. A probe card is used to test a test object to determine whether the object to be tested is matched to the requirement. The probe card is formed on a multilayer printed circuit board. The structure is very complicated and many probes are used to contact a series of electronic joints. The contact area is smaller than a hair. Before packing an IC, the bare crystal is tested by probes for removing bad products. The cost of probe card has a great percentage in the cost of manufacturing an IC. Generally, the probes includes arm probes (FIG. 1), vertical probes 12 (FIG. 2), spring probes 13 (FIG. 3), thin film probes 14 (FIG. 4), and micro-spring probes 15 (FIG. 5). In manufacturing process, a plurality of probes 11 are arranged on a base 16. Then the probes 11 are glued on the base 16. Then the probes 11 are welded to a printed circuit board 17. Then a probe card is used to grind the tips of the probes and the positions of the probes are detected and adjusted. Therefore, the process of producing a probe is complete. The contact end in the tip end of the probe contacts an electronic joint so as to measure the input signals about the electricity of the object to be tested for determining the yield ratio of the object to be tested.

Moreover, the tip of the probe will be worn due to friction, which will affect the reliability of the test result and the lifetime of the probe. The tip end of the probe is easy to wear as it is used for a long time and the end is not flat and thus dirt or dregs will adhere thereon. This will decrease the yield ratio of the object to be tested and more tests are necessary. Generally, sand papers are used to clean the tip end for sustaining a good yield ratio. However, if the tip will be worn due to the friction with the sand paper. Thus a further probe card is necessary. However, the cost of probe card is high. As a result, the test cost for an IC is increased. It is uneconomic. Furthermore the probes are arranged densely so that it is easy to short circuit between two adjacent probes due to undesired objects falling into the gaps between the probes. As a result the probe can not be operated normally.

### SUMMARY OF THE INVENTION

Accordingly, the primary object of the present invention is to provide a probe installed to a probe card, wherein the conductivity of the probe is increased and the probe is worn-endurable and friction endurable. The dirt and dregs on the surface of the probe is reduced. Electromagnetic interference is decreased and the probe can be trimmed easily. The probe can be reused again and again and the lifetime of the probe is prolonged. The yield ratio is increased and the cost in testing is reduced.

To achieve above objects, the present invention provides a probe installed to a probe card, wherein a tip and a body of the probe are electroplated with a conductive film with a conductivity greater than 1×10³ (m·Ω)⁻¹ and the probe card is placed in a vacuum electroplating furnace. Furthermore the present invention provide a probe installed to a probe card, wherein a tip of the probe is electroplated with a conductive film with a conductivity greater than 1×10³ (m·Ω)⁻¹ and the probe card is placed in a vacuum electroplating furnace.

Moreover, the present invention provides a probe installed to a probe card, wherein a body of the probe is electroplated with a conductive film with an insulating film and the probe card is placed in a vacuum electroplating furnace.

Further, a probe with worn conductive film is electroplated again with a conductive film.

The various objects and advantages of the present invention will be more readily understood from the following detailed description when read in conjunction with the appended drawing.

### BRIEF DESCRIPTION OF THE DRAWINGS

FIG. 1 is a schematic view about a prior art arm probe.

FIG. 2 is a schematic view showing the prior art vertical probe.

FIG. 3 is a schematic view showing the prior art spring probe.

FIG. 4 is a schematic view about the prior art thin film probe.

FIG. 5 is a schematic view about the prior art micro-spring probe.

FIG. 6 is a schematic view about the probe of the present invention.

FIG. 7 is a schematic view of the probe of the present invention.

FIG. 8 is a schematic view showing that a conductive film is coated on the surface of the probe according to the present invention.

FIG. 9 is a schematic view showing that a conductive film is coated on the surface of the tip of the probe according to the present invention.

FIG. 10 is a schematic view showing that an insulating film is coated on the surface of tip and body of the probe according to the present invention.

FIG. 11 is a schematic view showing that the body of the probe of the present invention is electroplated with a conductive film.

FIG. 12 is a schematic view showing that the body of the probe is electroplated with an insulating film according to the present invention.

FIG. 13 is a schematic view showing that the tip and body of the probe is electroplated with an insulating film.

FIG. 14 is a schematic view showing that the tip of the probe is electroplated with a conductive film and the body of the probe is electroplated with an insulating film.

FIG. 15 is a schematic view that the tip and body of the probe is electroplated with a conductive film and then the body is further electroplated with an insulating film according to the present invention.

FIG. 16 is a schematic view showing that the surface of the probe is electroplated with a conductive film and then the body of the probe is electroplated with an insulating film.

FIG. 17 is a schematic view showing that the conductive film of the probe is worn and then the probe is electroplated with a conductive film again.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

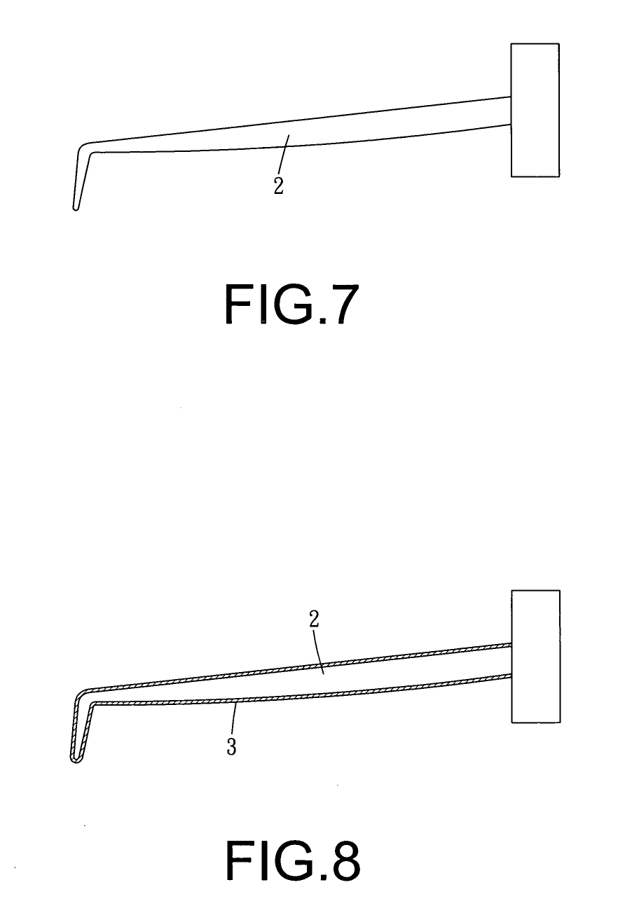

Referring to FIG. 7, the first embodiment of the present invention is illustrated. A probe card 1 with a probe 2 is placed in an electroplating furnace. The probe 2 is made of conductive metal, such as tungsten or tungsten alloy. The electroplating furnace may be a vacuum electroplating furnace. The probe card 1 is shielded and the probe 2 exposes out. The surfaces of the tip and body of the probe 2 are electroplated with a conductive film 3 (FIG. 8). The film is made of conductive material with conductivity greater than 1×10³ (m·Ω)⁻¹, such as tungsten, copper, aluminum, etc. The thickness of the conductive film 3 is between 0 and 1 mm. The material of the conductive film 3 is determined by the objects to be detected. The tip and body of the probe 2 can be electroplated with different materials. The conductive film 3 may be a single layer or multiple layer structure which can be the same material or different materials.

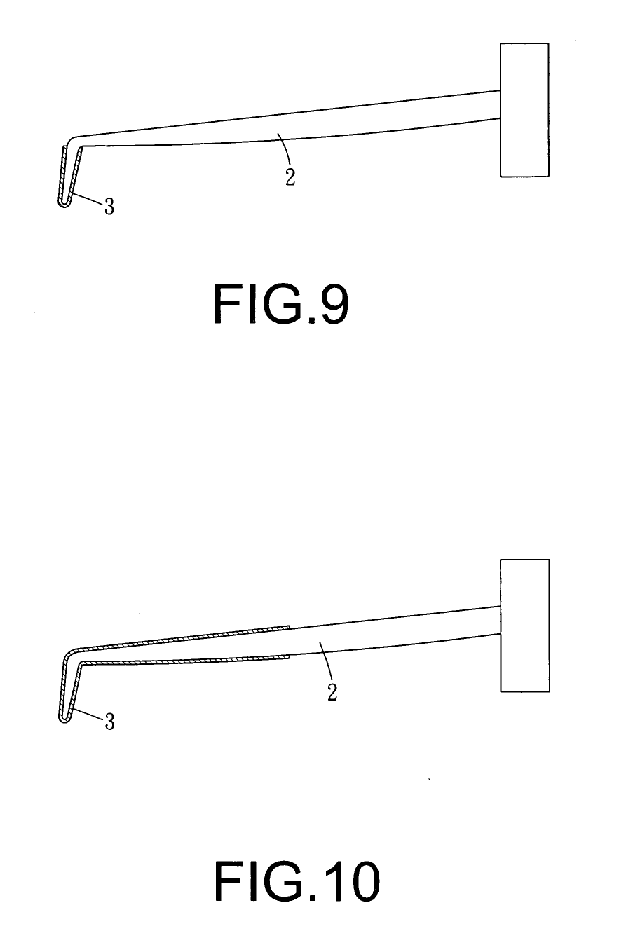

With reference to FIGS. 7 and 9, the second embodiment of the present invention is illustrated. A probe card with a probe 2 is placed in an electroplating furnace. The probe 2 is made of conductive metal, such as tungsten or tungsten alloy. The electroplating furnace may be a vacuum electroplating furnace. The probe card 1 and body of the probe 2 are shielded and the tip of the probe 2 exposes out. The surface of the tip of the probe 2 is electroplated with a conductive film 3 (FIG. 9). The film is made of conductive material with conductivity greater than 1×10³ (m·Ω)⁻¹, such as tungsten, copper, aluminum, etc. The thickness of the conductive film 3 is between 0 and 1 mm. The material of the conductive film 3 is determined by the objects to be detected. The tip of the probe 2 can be electroplated with different materials. The conductive film 3 may be a single layer or multiple layer structure which can be the same material or different materials. Furthermore the conductive film 3 can be extended to a part of the body of the probe 2, as shown in FIG. 10. It still has the same effect.

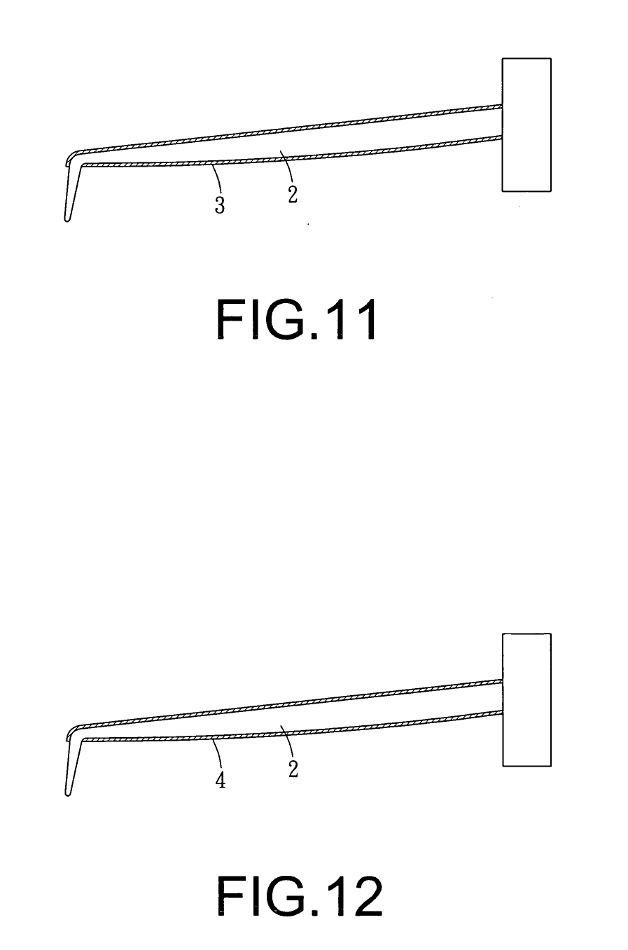

Referring to FIG. 11, the third embodiment of the present invention is illustrated. A probe card 1 with a probe 2 is placed in an electroplating furnace. The probe 2 is made of conductive metal, such as tungsten or tungsten alloy. The electroplating furnace may be a vacuum electroplating furnace. The probe card 1 and the tip of the probe 2 are shielded and the body of the probe 2 exposes out. The surface of the body of the probe 2 is electroplated with a conductive film 3 (FIG. 8). The film is made of conductive material with conductivity greater than 1×10³ (m·Ω)⁻¹, such as tungsten, copper, aluminum, etc. The thickness of the conductive film 3 is between 0 and 1 mm. The material of the conductive film 3 is determined by the objects to be detected. The body of the probe 2 can be electroplated with different materials. The conductive film 3 may be a single layer or multiple layer structure which can be the same material or different materials.

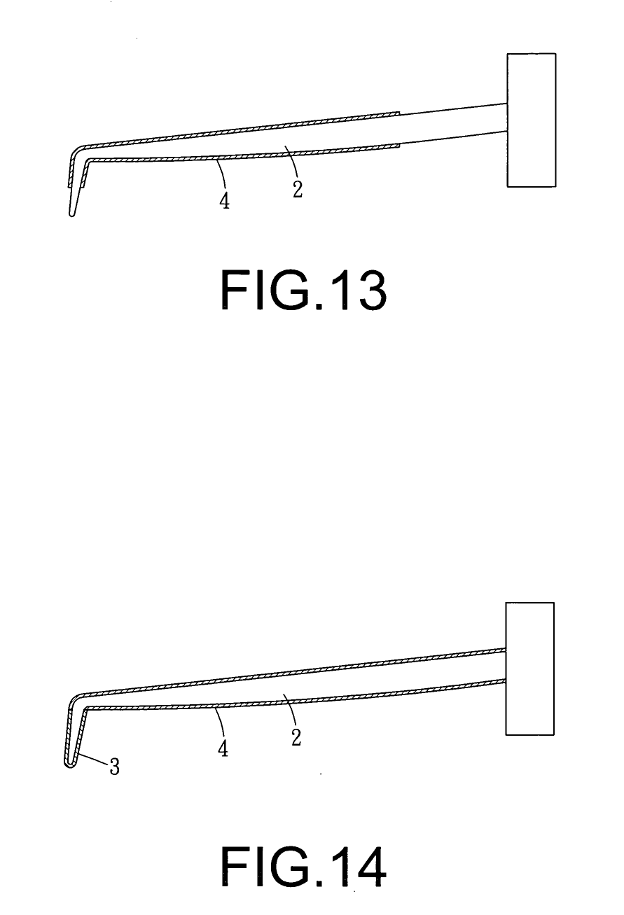

Referring to FIG. 12, the fourth embodiment of the present invention is illustrated. A probe card 1 with a probe 2 is placed in an electroplating furnace. The probe 2 is made of conductive metal, such as tungsten or tungsten alloy. The electroplating furnace may be a vacuum electroplating furnace. The probe card 1 and the tip of the probe 2 are shielded and the body of the probe 2 exposes out. The surface of the body of the probe 2 is electroplated with an insulating film 4 (FIG. 8). The thickness of the insulating film 4 is between 0 and 1 mm. The insulating film 4 avoids short circuit to occur in use of the probe 2 so that the probe 2 can operate steadily. The yield ratio is increased. The measurement can be performed accurately. Moreover, in the present invention, the insulating film 4 can extend to part of the tip of the probe 2, as shown in FIG. 13.

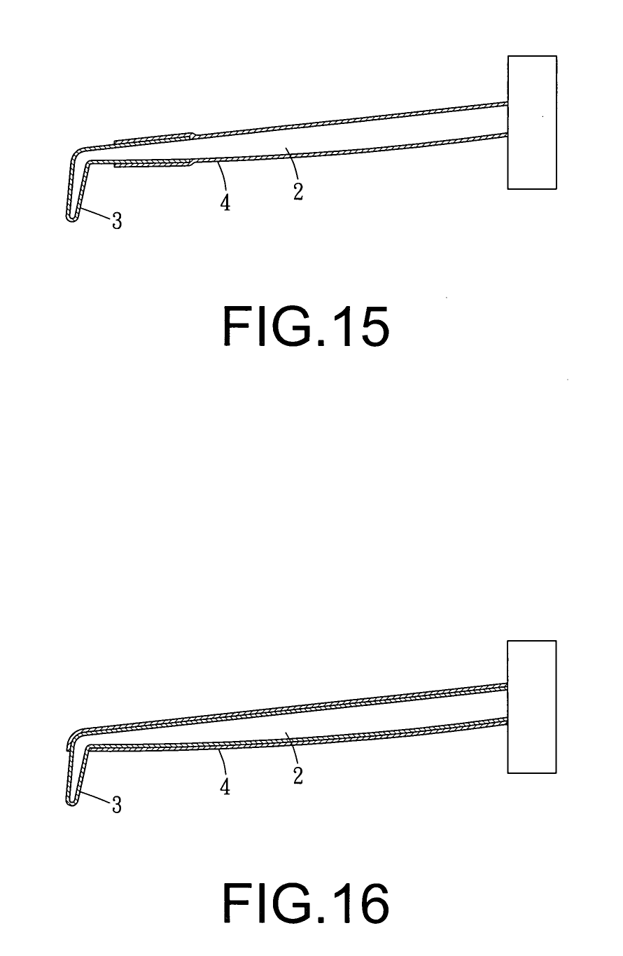

Referring to FIG. 14, the fifth embodiment of the present invention is illustrated. A probe card 1 with a probe 2 is placed in an electroplating furnace. The probe 2 is made of conductive metal, such as tungsten or tungsten alloy. The electroplating furnace may be a vacuum electroplating furnace. The probe card 1 and the body of the probe 2 are shielded and the tip of the probe 2 exposes out. The surface of the tip of the probe 2 is electroplated with a conductive film 3 by vacuum electroplating. The film is made of conductive material with conductivity greater than 1×10³ (m·Ω)⁻¹, such as tungsten, copper, aluminum, etc. The thickness of the conductive film 3 is between 0 and 1 mm. The material of the conductive film 3 is determined by the objects to be detected. The tip of the probe 2 can be electroplated with different materials. The conductive film 3 may be a single layer or multiple layer structure which can be the same material or different materials. Then the probe card 1 and the tip of the probe 2 are shield and the body of the probe 2 exposes out. The surface of the body of the probe 2 is electroplated with an insulating film 4. The thickness of the insulating film is between 0 and 1 mm. Moreover, the conductive film 3 can extend to part of the body of the probe 2 and then the surface of the body of the probe 2 is electroplated with the insulating film 4, as shown in FIG. 15.

Referring to FIG. 16, the sixth embodiment of the present invention is illustrated. A probe card 1 with a probe 2 is placed in an electroplating furnace. The probe 2 is made of conductive metal, such as tungsten or tungsten alloy. The electroplating furnace may be a vacuum electroplating furnace. The probe card 1 is shielded and the probe 2 exposes out. The surfaces of the tip and body of the probe 2 are electroplated with a conductive film 3 by vacuum electroplating (FIG. 8). The film is made of conductive material with conductivity greater than 1×10³ (m·Ω)⁻¹, such as tungsten, copper, aluminum, etc. The thickness of the conductive film 3 is between 0 and 1 mm. The material of the conductive film 3 is determined by the objects to be detected. The tip and body of the probe 2 can be electroplated with different materials. The conductive film 3 may include single or multiple layers which can be the same material or different materials. Then the probe card 1 and the tip of the probe 2 electroplated with conductive film 3 are shield. The body of the probe 2 electroplated with the conductive film 3 exposes out. The surface of the body is electroplated with an insulating film 4, as shown in FIG. 16. The thickness of the insulating film 4 is between 0 and 1 mm.

In the seventh embodiment of the present invention, a surface of the probe 2 is electroplated with a conductive film with a conductivity greater than 1×10³ (m·Ω)⁻¹, such as tungsten, copper, aluminum, etc. The thickness of the film is between 0 and 1 mm. The material of the conductive film is determined by the objects to be detected. The tip and body of the probe can be electroplated with different materials. The conductive film may be a single layer or multiple layer structure which can be the same material or different materials. Then the probe 2 is further electroplated with an insulating film 4 with a thickness between 0 and 1 mm. The probe is installed to a probe card 1. The tip of the probe is grounded and the tip of the probe installed to the probe card is electroplated with a conductive film with a conductivity greater than 1×10³ (m·Ω)⁻¹. The thickness of the film is between 0 to 1 mm.

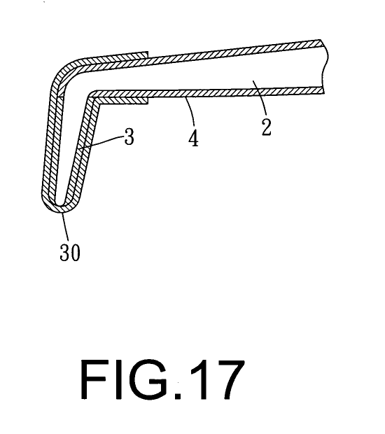

When the probe 2 is used, the conductive film 3 of the surface of the tip of the probe 2 will wear and the dirt or dregs are adhered on the conductive film 3. However, in the present invention, they can be cleaned and then electroplated again. Firstly, the probe 2 of the probe card 1 is trimmed and the portion of the probe 2 not to be electroplated is shielded. Only the tip of the probe 2 exposes out. The shielded probe card 1 and the probe 2 are placed in an electroplating furnace. The unshielded tip is electroplated with a film 30 as a protection layer (FIG. 17). Thus the probe 2 is not worn. Only the surface of the probe 2 covered with the film 3 is worn and then is trimmed for electroplating again.

Generally, the probe is worn due to friction. This will affect the reliability and lifetime of the probe. The film on the surface of the probe will prolong the lifetime of the probe 2 on the probe card 1. In use of the probe 2, the probe 2 will be in contact with the object to be tested so that the material of the object will adhere to the surface of the probe 2. In the present invention, the probe 2 is electroplated with a conductive film 3 with is worn-endurable. The surface thereof is smooth and the adhesion of the material of the object to be test is reduced. Furthermore the dirt can be removed easily and the yield ratio is increased.

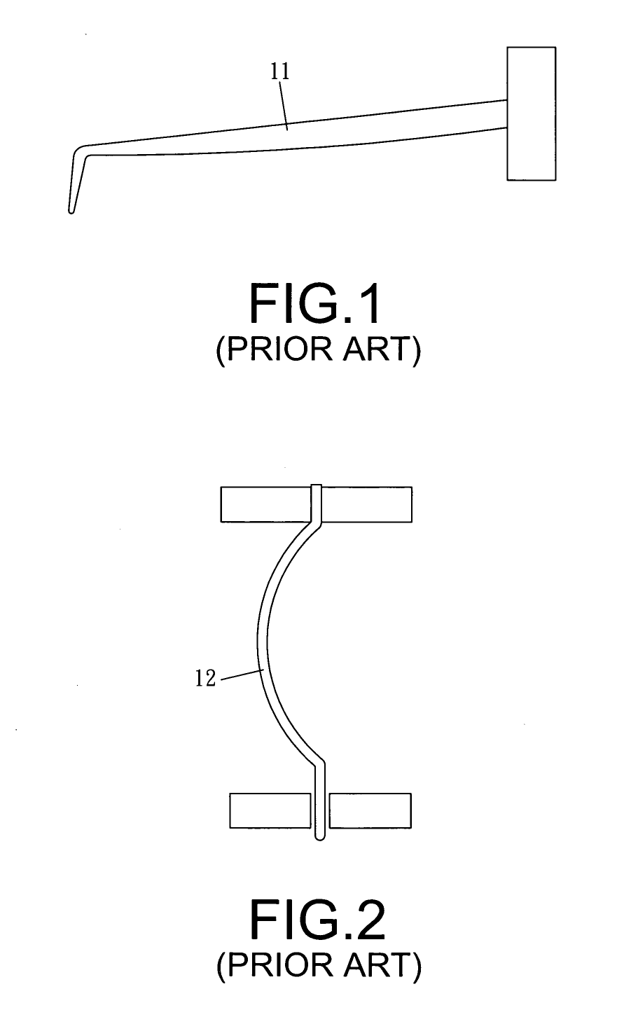

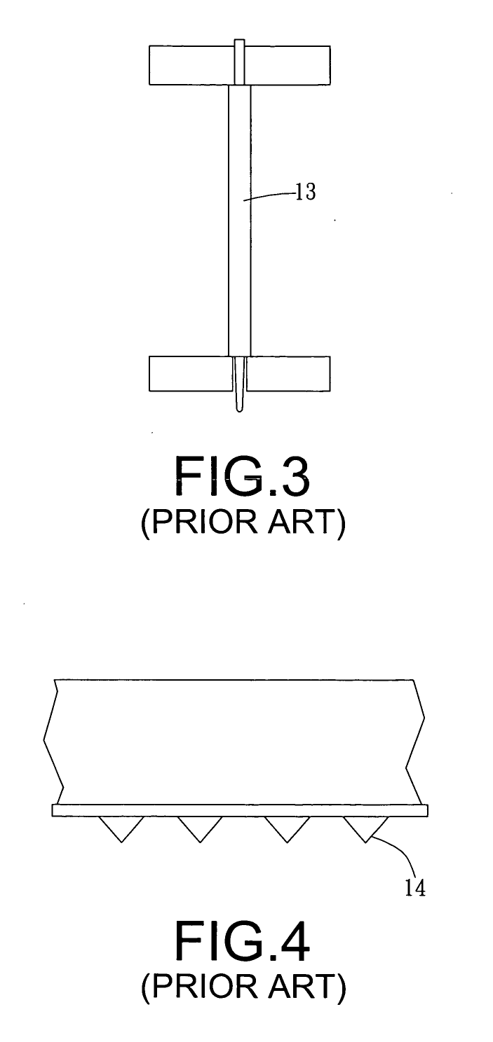

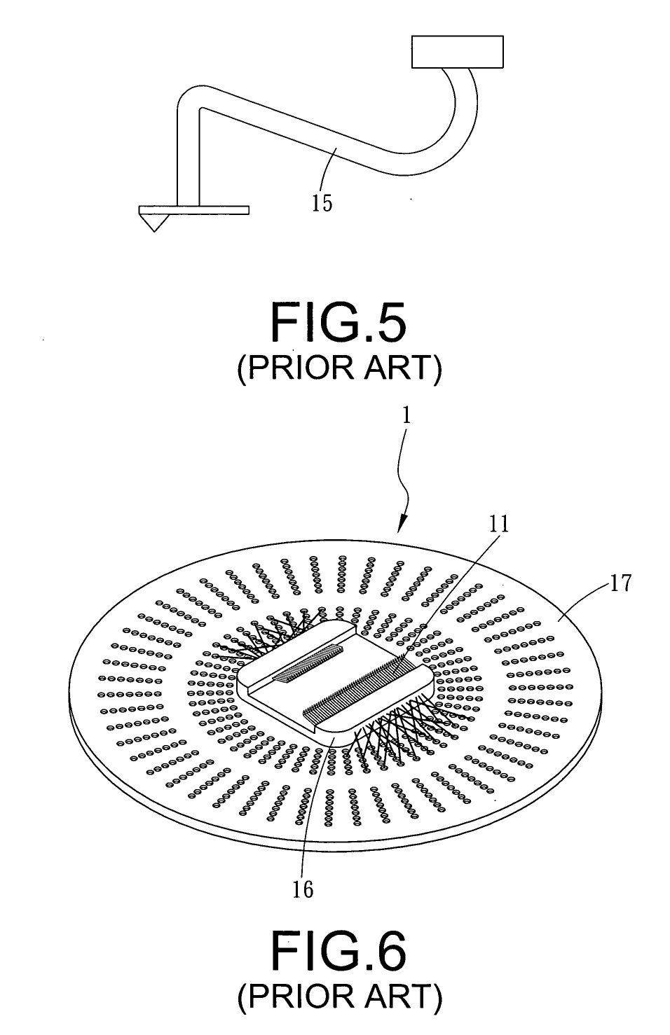

The probe 2 of the present invention may be an arm probe 11 (FIG. 1), a vertical probe 12 (FIG. 2), a spring probe 13 (FIG. 3), a film probe 14 (FIG. 4), a micro-spring probe 15 (FIG. 4), etc. The above mentioned probes are coated with film 3 or insulating film 4.

Advantages of the present invention will be described herein. The conductive film coated on the probe in the probe card can increase the conductivity of the probe and reduces the contact impedance of the probe.

The surface processing on the surface of the probe will increase the wear-endurance of the probe and reduce the dirt or dregs adhered to the surface of the probe. Furthermore the dirt and dregs can be removed easily.

The film on the surface of the probe can be trimmed easily and the electroplating can be performed repeatedly so as to prolong the lifetime of the probe.

The insulating film on the surface of the probe will prevent the probe from short circuit so that the probe can operate steadily.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A probe with a probe card comprising a probe made of conductive metal and a probe card; the probe being installed upon the probe card, wherein a tip and a body of the probe having coated with a conductive film with a conductivity greater than 1×10³ (m·Ω)⁻¹ and the tip of the probe is bent downwards.

2. A probe with a probe card comprising a probe and a probe card; the probe being installed upon the probe card, wherein a tip of the probe is coated with a conductive film with a conductivity greater than 1×10³ (m·Ω)⁻¹ and the tip of the probe is bent downwards.

3. A probe with to a probe card comprising a probe and a probe card; the probe being installed upon the probe card, wherein a body of the probe is coated with an insulating film and the probe card is bent downwards.

4-5. (canceled)

6. The probe with a probe card as claimed in claim 1, wherein the conductive metal is selected from of tungsten and tungsten alloy; and the conductive film is made of a material selected from one of tungsten, copper, and aluminum.

7. The probe with a probe card as claimed in claim 6, wherein a thickness of the conductive film is between 0 and 1 mm; and the conductive film is a multiple layer structure.

8. The probe with a probe card as claimed in claim 2, wherein the conductive metal is selected from of tungsten and tungsten alloy; and the conductive film is made of a material selected from one of tungsten, copper, and aluminum.

9. The probe with a probe card as claimed in claim 8, wherein a thickness of the conductive film is between 0 and 1 mm; and the conductive film is a multiple layer structure.

10. The probe with a probe card as claimed in claim 3, wherein the conductive metal is selected from of tungsten and tungsten alloy; and the conductive film is made of a material selected from one of tungsten, copper, and aluminum.

11. The probe with a probe card as claimed in claim 10, wherein a thickness of the conductive film is between 0 and 1 mm; and the conductive film is a multiple layer structure.
